(19) United States
(12) Patent Application Publication
(10) Pub. No.: US 2024/0095518 A1
(43) Pub. Date: Mar. 21, 2024

(54) STRUCTURED SPARSE MEMORY HIERARCHY FOR DEEP LEARNING

(71) Applicant: Samsung Electronics Co., Ltd., Suwon-si (KR)

(72) Inventors: Ardavan PEDRAM, Santa Clara, CA (US); Jong Hoon SHIN, San Jose, CA (US); Joseph H. HASSOUN, Los Gatos, CA (US)

(21) Appl. No.: 17/988,739

(22) Filed: Nov. 16, 2022

Related U.S. Application Data
(60) Provisional application No. 63/408,827, filed on Sep. 21, 2022.
(60) Provisional application No. 63/408,828, filed on Sep. 21, 2022.
(60) Provisional application No. 63/408,829, filed on Sep. 21, 2022.
(60) Provisional application No. 63/410,216, filed on Sep. 26, 2022.

(51) Int. Cl. G06N 3/08

(52) U.S. Cl. CPC G06N 3/08

(57) ABSTRACT

A memory system and a method are disclosed for training a neural network model. A decompressor unit decompresses an activation tensor to a first predetermined sparsity density based on the activation tensor being compressed, and decompresses an weight tensor to a second predetermined sparsity density based on the weight tensor being compressed. A buffer unit receives the activation tensor at the first predetermined sparsity density and the weight tensor at the second predetermined sparsity density. A neural processing unit receives the activation tensor and the weight tensor from the buffer unit and computes a result for the activation tensor and the weight tensor based on first predetermined sparsity density of the activation tensor and based on the second predetermined sparsity density of the weight tensor.

### CROSS-REFERENCE TO RELATED APPLICATION

This application claims the priority benefit under 35 U.S.C. § 119(e) of U.S. Provisional Application No. 63/408,827, filed on Sep. 21, 2022, 63/408,828, filed on Sep. 21, 2022, 63/408,829, filed on Sep. 21, 2022, and 63/410,216, filed on Sep. 26, 2022, the disclosures of which are incorporated herein by reference in their entirety.

### TECHNICAL FIELD

The subject matter disclosed herein relates to neural networks. More particularly, the subject matter disclosed herein relates to a system and a method for training a neural network model.

### BACKGROUND

Deep neural networks (DNNs) may be accelerated by Neural Processing Units (NPUs). The operand sparsity associated with General Matrix Multiply (GEMM) operations in DNNs may be used to accelerate operations performed by NPUs. Fine-grained structured sparsity, especially N:M sparsity (N nonzero elements out of M weight values), may be helpful to maintain accuracy and save hardware overhead compared to random sparsity. Existing technology related to structured sparsity, however, only supports weight sparsity.

### SUMMARY

An example embodiment provides a memory system for training a neural network model that may include a decompressor unit, a buffer unit, and a neural processing unit. The decompressor unit may be configured to decompress an activation tensor to a first predetermined sparsity density based on the activation tensor being compressed, and to decompress an weight tensor to a second predetermined sparsity density based on the weight tensor being compressed. The buffer unit may be configured to receive the activation tensor at the first predetermined sparsity density and the weight tensor at the second predetermined sparsity density. The neural processing unit may be configured to receive the activation tensor and the weight tensor from the buffer unit and to compute a result for the activation tensor and the weight tensor based on first predetermined sparsity density of the activation tensor and based on the second predetermined sparsity density of the weight tensor. In one embodiment, the first predetermined sparsity density may be based on a structured-sparsity arrangement or a random-sparsity arrangement. In another embodiment, the first predetermined sparsity density may be based on a 1:4 structured-sparsity arrangement, or a 2:8 structured-sparsity arrangement. In still another embodiment, the second predetermined sparsity density may be based on a structured-sparsity arrangement or a random-sparsity arrangement. In yet another embodiment, the second predetermined sparsity density may be based on a 1:4 structured-sparsity arrangement or a 2:8 structured-sparsity arrangement. In one embodiment, the second predetermined sparsity density may be based on a structured-sparsity arrangement or a random-sparsity arrangement. In another embodiment, the second predetermined sparsity density may be based on a 1:4 structured-sparsity arrangement or a 2:8 structured-sparsity arrangement. In still another embodiment, the decompressor unit may be further configured to decompress the activation tensor to the first predetermined sparsity density using first metadata associated with the activation tensor and may be configured to decompress the weight tensor to the second predetermined sparsity density using second metadata associated with the weight tensor. In yet another embodiment, the memory system may further include a compressor unit configured to receive and compress the result computed by the neural processing unit, and a memory that further stores the result compressed by the compressor unit. In one embodiment, the compressor unit may further be configured to generate metadata associated with the result, and the memory may further store the metadata.

An example embodiment provides a memory system for training a neural network model that may include a buffer unit, and a dual-sparsity neural processing unit. The buffer unit may be configured to receive at least one activation tensor and at least one weight tensor in which the activation tensor may include a first predetermined sparsity density that may be based on a first structured-sparsity arrangement or a first random-sparsity arrangement, and the weight tensor may include a second predetermined sparsity density that may be based on a second structured-sparsity arrangement or a second random-sparsity arrangement. The dual-sparsity neural processing unit may be configured to receive the activation tensor and the weight tensor from the buffer unit and to compute a result for the activation tensor and the weight tensor based on the first predetermined sparsity density of the activation tensor and based on the second predetermined sparsity density of the weight tensor. In one embodiment, the memory system may further include a decompressor unit configured to decompress the activation tensor to the first predetermined sparsity density and output the activation tensor to the buffer unit. In another embodiment, the decompressor unit may be further configured to decompress the weight tensor to the second predetermined sparsity density and output the weight tensor to the buffer unit. In still another embodiment, the decompressor unit may be further configured to decompress the activation tensor to the first predetermined sparsity density using first metadata associated with the activation tensor and may be configured to decompress the weight tensor to the second predetermined sparsity density using second metadata associated with the weight tensor. In yet another embodiment, the memory system may further include a decompressor unit that may be configured to decompress the weight tensor to the second predetermined sparsity density and to output the weight tensor to the buffer unit. In one embodiment, the first predetermined sparsity density may be based on a 1:4 structured-sparsity arrangement, or a 2:8 structured sparsity-arrangement. In another embodiment, the second predetermined sparsity density may be based on a 1:4 structured-sparsity arrangement or a 2:8 structured-sparsity arrangement. In still another embodiment, the memory system may further include a compressor unit configured to receive and compress the result computed by the dual-sparsity neural processing unit, and a memory that further stores the result compressed by the compressor unit. In one embodiment, the compressor unit may be further configured to generate metadata associated with the result, and the memory may further store the metadata.

### BRIEF DESCRIPTION OF THE DRAWING

In the following section, the aspects of the subject matter disclosed herein will be described with reference to exemplary embodiments illustrated in the figure, in which:

FIG. 1 depicts an example dot-product operation, which is commonly performed in a neural network for a deep learning inference;

FIG. 2 depicts an example array of elements, which may be activation values or weight values, arranged in an example N:M=4:8 or 2:4 structured-sparsity format;

FIG. 3 depicts an example of a set of dense weights values being formed into an N:M structured sparse set of weight values;

FIG. 4 is a block diagram of an example embodiment of a memory system for training a neural network model according to the subject matter disclosed herein;

FIG. 5 is a functional block diagram of an example embodiment of compressor unit of a compressor/decompressor unit according to the subject matter disclosed herein;

FIG. 6 is a functional block diagram of an example embodiment of a decompressor unit of a compressor/decompressor unit according to the subject matter disclosed herein;

FIG. 7A depicts an example embodiment of a reconfigurable dual-sparsity NPU that may be part of a neural processing core according to the subject matter disclosed herein;

FIG. 7B depicts a second example embodiment of a reconfigurable dual-sparsity NPU that may be part of a neural processing core according to the subject matter disclosed herein;

FIG. 8 is a flow diagram of a method for training a neural network model using a memory system according to the subject matter disclosed herein; and

FIG. 9 depicts an electronic device that may include a memory hierarchy that may be used to train a neural network model according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The subject matter disclosed herein provides a memory hierarchy for deep learning. In one embodiment, the memory hierarchy provides data locality in proximity to sparse cores that perform the deep-learning inference calculations and provides compression and decompression functionality, thereby reducing traffic to, for example, off-chip memory and other levels of memory hierarchy and reducing power consumption.

The subject matter disclosed herein provides a system architecture design for training structured sparse deep neural networks. In one embodiment, structured sparse cores are configured for dual-structured sparse tensor computations. That is, the structured sparse cores are configured for both activation tensors and weight tensors in structured-sparsity modes. Further, the structured sparsity cores may be configured for random sparsity for both activation and weight tensors. Further still, the structured sparsity cores may be configured for a combination of structured sparsity and random sparsity for both activation and weight tensors. In another embodiment, sparse memory hierarchy components including compressors and decompressors are used to reduce both computations, memory traffic and storage size.

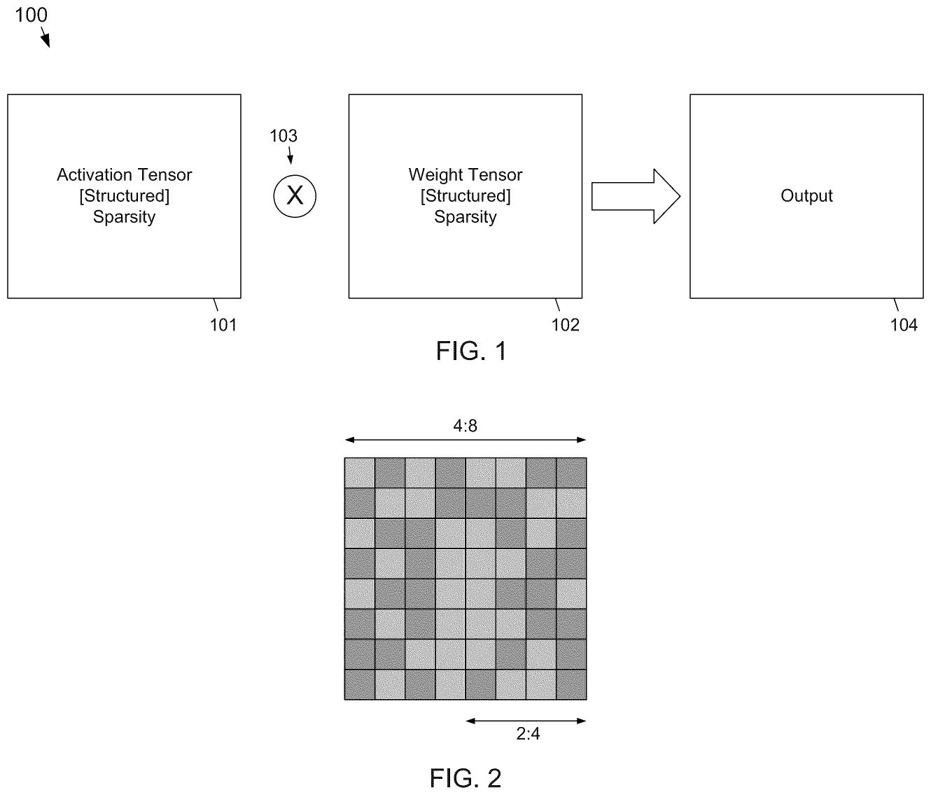

FIG. 1 depicts an example dot-product operation 100, which is commonly performed in a neural network for a deep learning inference. The dot product of a first tensor a=[a₁, a₂, . . . , aₙ] and a second tensor w=[w₁, w₂, . . . , wₙ] is defined as

a·w=Σᵢ₌₁ⁿaᵢwᵢ=a₁w₁,+a₂w₂+ . . . +aₙwₙ (1)

in which Σ denotes a summation, i is an index, and n is the dimension of the vector (tensor) space.

Referring to FIG. 1, the first tensor a may be an activation tensor 101 that may or may not be arranged in a structured-sparsity format. The second tensor w may be a weight tensor 102 that may or may not be arranged in a structured-sparsity format. A dot-product operation 103 of the first tensor a and the second tensor w is indicated at an output 104.

FIG. 2 depicts an example array of elements, which may be activation values or weight values, arranged in an example N:M=4:8 or 2:4 structured-sparsity format in which in a defined group (such as a row, not a column) of M consecutive weights, there are at most N weights have a non-zero value. The elements of the array are indicated by small squares, and the two different shades of gray of the elements represent zero-valued elements and non-zero-valued elements. The 4:8 and the 2:4 structured sparsity arrangement shown results in either shade of gray representing a zero-valued element or a non-zero-valued element. Structured sparsity is not limited to the 4:8 and the 2:4 structured-sparsity arrangements indicated in FIG. 2, and may also include 1:4 and 2:8 structured sparsity arrangements.

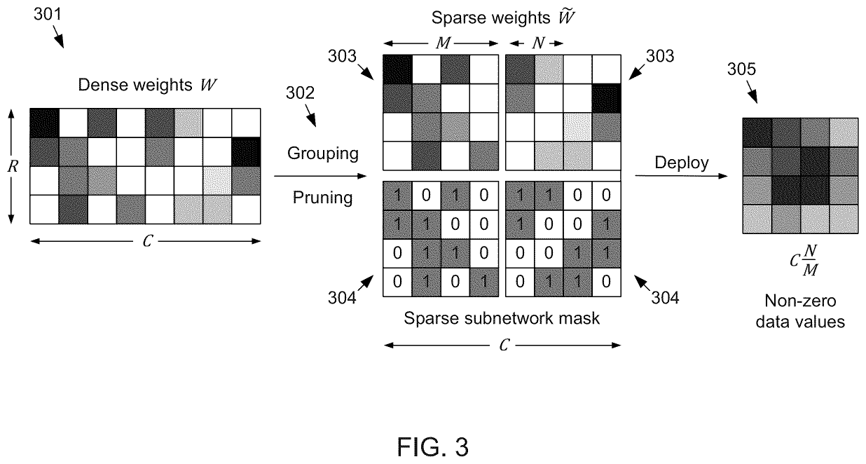

FIG. 3 depicts an example of a set of dense weights values being formed into an N:M structured sparse set of weight values. The dense weights values W are depicted in an example matrix at 301 in which R is the number of output channels and C is the number of channels in a linear layer of neural network. Relative values are depicted as light and dark matrix elements (blocks) in which relatively lower-value elements are depicted as lighter gray and relatively higher-value elements are depicted as darker grays. At 302, the weight values W are grouped into 4×4 groups 303 prior to pruning. Sparse subnetwork masks for the two weight groups are indicated at 304. After pruning, the pruned weights are deployed at 305 in a N:M structured sparse arrangement in which in each group of M consecutive weights, there are at most N weights have a non-zero value. The

$$C \frac{N}{M}$$

indicated at 205 means that as only N elements out of M weights in C channels are kept, the channel size of the weight tensor shrinks from C to

$$C \frac{N}{M} .$$

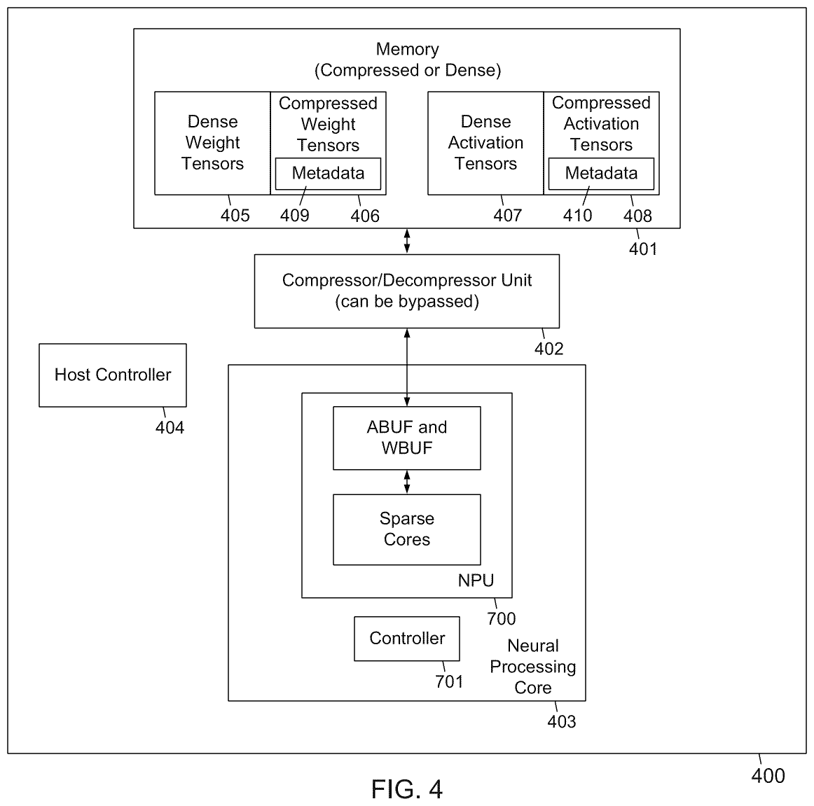

FIG. 4 is a block diagram of an example embodiment of a memory system 400 for training a neural network model according to the subject matter disclosed herein. The memory system 400 includes a memory 401, a compressor/decompressor unit 402, a neural processing core 403 and a host controller 404.

The memory 401 may store dense weight tensors 405 and/or compressed weight tensors 406. Additionally, the memory 401 may store dense activation tensors 407 and/or compressed activation tensors 408. The memory 401 may also store dense and/or compressed weight matrices, and dense and/or compressed activation matrices. The terms “tensor” or “tensors” will be used herein for convenience, and it should be understood that the terms “matrix” or “matrices” may be also be used herein interchangeably with the terms “tensor” and “tensors.” Metadata 409 that is associated with the compressed weight tensors may be stored in the memory 401. Similarly, metadata 410 that is associated with the compressed activation tensors may be stored in the memory 401.

The compressor/decompressor unit 402 is coupled to the memory 401 and the NPU 403, and may decompress or compress tensors generally depending on the direction the tensors are flowing during training of the neural network model. For example, if the tensors are flowing from the memory 401 toward the NPU 403 and are compressed, the compressor/decompressor unit 402 decompresses the tensors. If the tensors are flowing from the memory 401 toward the NPU 403 and are uncompressed, the tensors may bypass the compressor/decompressor unit 402. If the tensors are flowing from the NPU 403 toward the memory 401, the compressor/decompressor unit 402 compresses the tensors based on whether the tensors are to be compressed. Dense tensors may also flow from the memory 401 to the compressor/decompressor unit 402 for compression before flowing back to the memory 401 for storage. Likewise, compressed tensors may flow from the memory 401 to the compressor/decompressor unit 402 for decompression before flowing back to the memory 401 for storage. In one embodiment, the compressor/decompressor unit 402 may use a zero-value coding for compressing and decompressing tensors, and which is suitable for the ranges of sparsity of about 50-75% sparsity that are expected to be processed by the sparse cores of the system. Other coding techniques are also possible.

The neural processing core 403 may include one or more neural processing units (NPUs) 700 and a controller 701 that may control movement of tensor elements between activation buffers (ABUFs), weight buffers (WBUFs) and multipliers (MULTs) that are internal to the NPU 700. In general, the neural processing core 403 receives weight and activation tensors, and computes output activation tensors. The output activation tensors may be directly transferred to the memory 401 or may pass through the compressor/decompressor unit 402 for compression before storage in the memory 401. The one or more NPUs 700 of the neural processing core 403 may be configured to process structured sparsity arrangements of 1:4, 2:4, 2:8 and 4:8 for both weights and activations while also being capable of processing random sparsity arrangements for weights and activations.

The host controller 404 is configured to control operation of the memory system 400 during training of a neural network model. In one embodiment, the host controller 404 may receive operational parameters that are used to train a neural network models, such as, but not limited to, the sparsity arrangement of the weight tensors and the activation tensors, pruning parameters, and one or more compression modes that may be used.

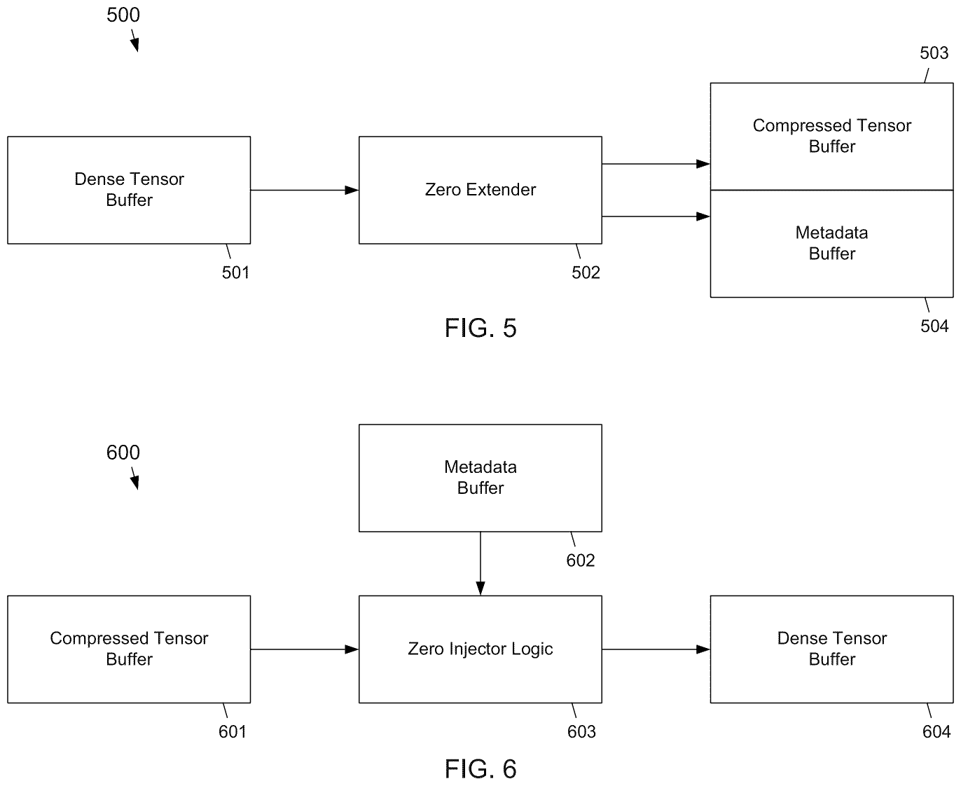

FIG. 5 is a functional block diagram of an example embodiment of a compressor unit 500 of the compressor/decompressor unit 402 according to the subject matter disclosed herein. The compressor unit 500 includes a dense matrix buffer 501 that is configured to receive dense tensors. The dense tensors are input to a zero extender unit 502 that removes zero-valued elements from the tensors to generate compresses tensors that are output to a compressed tensor buffer 503. The zero extender unit 502 also generates metadata that is associated with the compressed tensors and is output to a metadata buffer 504. The contents of the compressed tensor buffer 503 and the metadata buffer 504 may be transferred to the memory 401 during operation. The different units forming the compressor unit 500 may be formed from modules and may be combined depending on design.

FIG. 6 is a functional block diagram of an example embodiment of a decompressor unit 600 of the compressor/decompressor unit 402 according to the subject matter disclosed herein. The decompressor unit 600 includes a compressed tensor buffer 601 that is configured to receive compressed tensors. Metadata associated with the compressed tensors is received by a metadata buffer 602. The compressed tensors are input to a zero injector logic 603 that injects zero-value elements based on the metadata in the metadata buffer 602. The zero injector logic 603 outputs the dense tensor to a dense tensor buffer 604. The contents of the dense tensor buffer 604 may be transferred to the NPU 403 or to the memory 401 during operation. The different units forming the decompressor unit 600 may be formed from modules and may be combined depending on design.

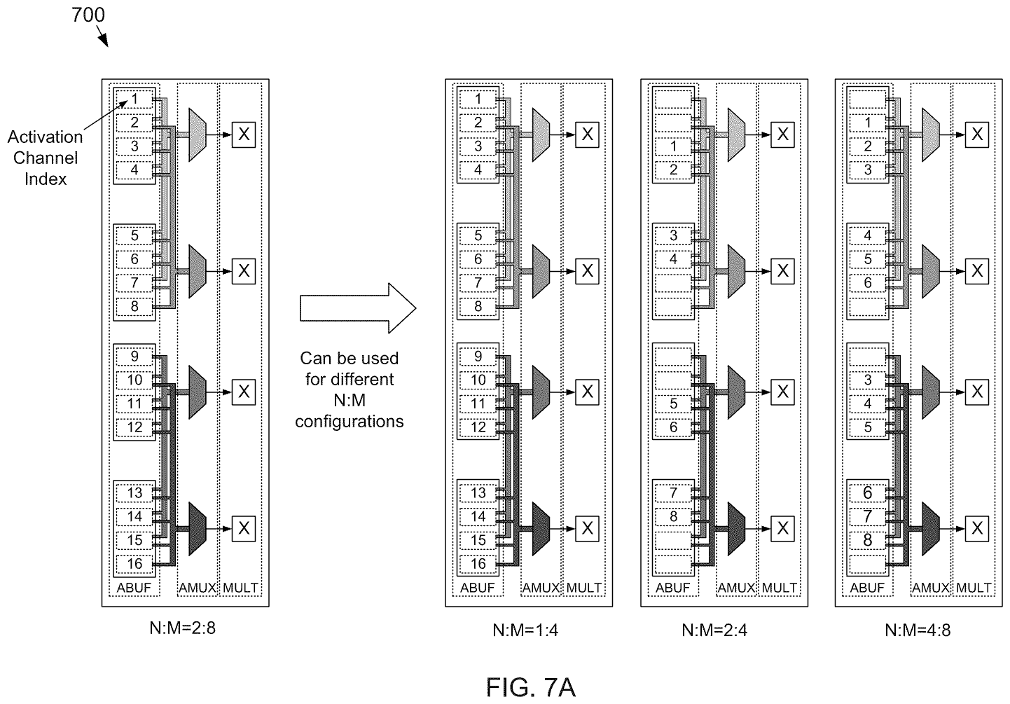

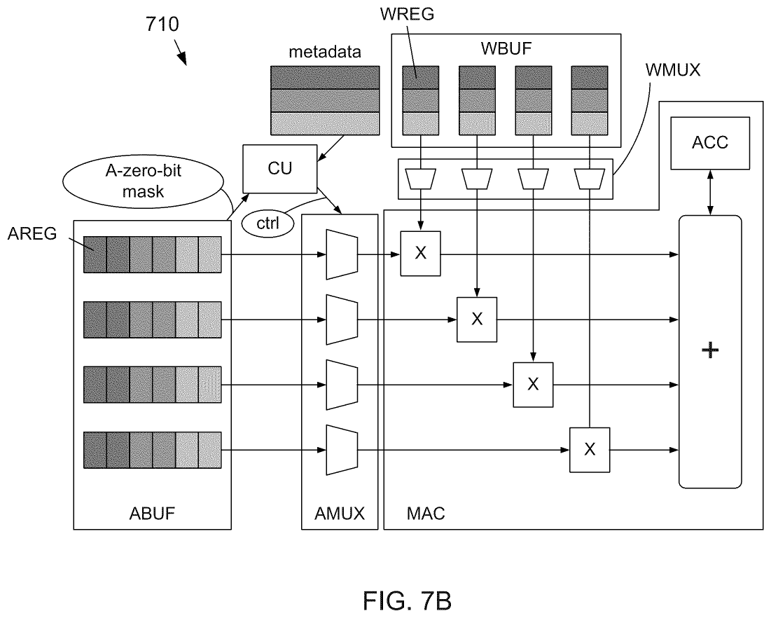

FIG. 7A depicts an example embodiment of a reconfigurable dual-sparsity NPU 700 that may be part of the neural processing core 403 according to the subject matter disclosed herein. The NPU 700 may be reconfigurable for processing structured sparsity arrangements of 1:4, 2:4, 2:8 and 4:8 for both weights and activation while also being capable of processing random sparsity arrangements for both or either weights and activations. Additional details of the reconfigurable NPU 700 may be found in U.S. patent application Serial No. (Attorney Docket 1535-849 and 1535-849), both of which are incorporated by reference herein.

The example embodiment of NPU 700 depicted in FIG. 7A may include four multipliers that are configured in an MULT array. The multipliers in a MULT array are indicated by a block containing an X. The NPU 700 may also include four activation multiplexers that are configured in an AMUX array. The multiplexers in an AMUX array are indicated by trapizoidal shapes. The activation buffers may be configured as four four-register buffers and are arranged in an ABUF array. Each multiplexer of the AMUX array may be a 7-to-1 multiplexer. The inputs to two of the multiplexers of the AMUX array may be connected to two four-register buffers as indicated. The connections between the multiplexers of the AMUX and the registers of the ABUF may be as shown in FIG. 7A.

The architecture of the NPU 700 may be used for structured weight sparsity arrangements of 1:4, 2:4, 2:8 and 4:8 by selective placement of activation values in the registers of the ABUF. Referring to FIG. 7A, the respective activation channels may be indexed, as indicated at the leftmost side of each NPU 700 configuration. The channel indexing changes based on which of the four structured sparsity arrangements for which the NPU 700 has been configured.

When the NPU 700 is configured for a 2:8 structured weight sparsity, the connections between the ABUF, AMUX and MULT arrays are depicted above the N:M=2:8 configuration. Sixteen activation channels are each input to a corresponding ABUF array register. The AMUX array multiplexers are controlled by a controller (not shown in FIG. 7A) to select an appropriate ABUF register based, for example, on a weight zero-bit mask or weight metadata associated with the 2:8 structured weight sparsity values. When the NPU 700 is configured for a 2:8 structured weight sparsity, the NPU 700 is also capable of operating in a random sparsity mode of (T_{w}, C_{w}, K_{w})=(3,1,0) in which T_{w} is a lookahead in time, C_{w} is a lookaside in input-channel, and K_{w} is a lookaside in output channel and the w subscript indicates weights.

When the NPU 700 is configured for a 1:4 structured weight sparsity, the connections between the ABUF, AMUX and MULT arrays are depicted above the N:M=1:4 configuration. The N:M=1.4 configuration is the same as the N:M=2:8 configuration. For the N:M=1:4 configuration, 16 activation channels are each input to a corresponding ABUF array register. The AMUX array multiplexers are controlled by a controller (not shown) to select an appropriate ABUF register based, for example, on a weight zero-bit mask or weight metadata associated with the 1:4 structured weight sparsity values. When the NPU 700 is configured for a 1:4 structured weight sparsity, the NPU 700 is also capable of operating in a random sparsity mode of (T_{w}, C_{w}, K_{w})=(3,0,0).

When the NPU 700 is configured for a 2:4 structured weight sparsity, the connections between the ABUF, AMUX and MULT arrays are depicted above the N:M=2:4 configuration. For the N:M=2:4 configuration, eight activation channels are each input to a corresponding ABUF array register as indicated. The AMUX array multiplexers are controlled by a controller (not shown) to select an appropriate ABUF register based, for example, on a weight zero-bit mask or weight metadata associated with the 2:4 structured weight sparsity values. When the NPU 700 is configured for a 2:4 structured weight sparsity, the NPU 700 is also capable of operating in a random sparsity mode of (T_{w}, C_{w}, K_{w})=(1,1,0).

When the NPU 700 is configured for a 4:8 structured weight sparsity, the connections between the ABUF, AMUX and MULT arrays are depicted above the N:M=4:8 configuration. For the N:M=4:8 configuration, eight activation channels are each input to a corresponding ABUF array register as indicated. More specifically, the two topmost multipliers have access to channels 1-6. The topmost multiplier has access to channels 1-5, and the next multiplier down has access to channels 2-6. Additionally, the two bottom most multipliers have access to channels 3-6, in which the third multiplier from the top has access to channels 3-7 and the bottom multiplier has access to channels 4-8. The AMUX array multiplexers are controlled by a controller (not shown) to select an appropriate ABUF register based, for example, on a weight zero-bit mask or weight metadata associated with the 4:8 structured weight sparsity values. When the NPU 700 is configured for a 4:8 structured weight sparsity, the NPU 700 is also capable of operating in a random sparsity mode of (T_{w}, C_{w}, K_{w})=(3,1,0).

FIG. 7B depicts a second example embodiment of a reconfigurable dual-sparsity NPU 710 that may be part of the neural processing core 403 according to the subject matter disclosed herein. The example dual-sparsity NPU 710 is configured for a 2:4 structured weight sparsity that includes a 2-cycle activation lookahead. Similar to NPU 700, the reconfigurable dual-sparsity NPU 710 may also be used to support 1:4, 4:8 and 2:8 structured-sparsity modes in addition to the 2:4 structured-sparsity mode.

The NPU 710 may include a multiply and accumulate (MAC) unit having an array of four multipliers (each indicated by a block containing an X). The accumulator portion of the MAC unit includes an adder tree (indicated by a block containing a +) and an accumulator ACC. Additionally, the NPU architecture 710 may include a weight buffer WBUF array that contains a depth of 3 weight registers WREGs for each multiplier of the MAC unit, and an activation buffer ABUF contains a depth of 6 activation registers AREGs for each multiplier of the MAC unit. An activation multiplexer AMUX may include an activation multiplexer (indicated by a trapezoidal shape) for each multiplier of the MAC unit. Although not explicitly shown, each activation multiplexer has a fan in of 9. That is, each activation multiplexer is a 9-to-1 multiplexer. A control unit (controller 701) receives an activation zero-bit mask (A-zero-bit mask) and weight metadata in order to control (ctrl) the multiplexers of the AMUX to select appropriate AREGs. In operation, a weight value in a WREG is input to a multiplier as a first input. The activation zero-bit mask and weight metadata is used to control the multiplexers of the AMUX to select an appropriate AREG in the ABUF corresponding to each weight value. The activation value in a selected AREG is input to a multiplier as a second input corresponding to first input to the multiplier. The NPU 710 provides a speed up of ˜3× over a NPU architecture configured only for weight sparsity. Additional details of the reconfigurable NPU 700 may be found in U.S. patent application Serial No. (Attorney Docket 1535-849 and 1535-849), both of which are incorporated by reference herein.

The NPU 710 may also be used for random weight sparsity operations. That is, the example NPU 710 is also configured for a random sparsity mode of (T_{w}=1, C_{w}=1, Tₐ=2). For random weight sparsity, the effective activation lookahead the NPU 710 is 5 cycles based on the 6 AREG depth of the ABUF with a maximum speed up of 6× (typically 2×) over a NPU architecture configured for only weight sparsity. Regarding weight preprocessing of random weight sparsity, if the weight mask is updated infrequently, software-based preprocessing may be used. If the weight mask is updated frequently, then hardware-based preprocessing by adding a weight-preprocessing unit may be a better approach.

Although the example embodiment of the dual-sparsity NPU 710 is configured for a 2:4 structured weight sparsity that includes a 2-cycle activation lookahead, the NPU 700 may be configured for other structured sparsity arrangements that also provide capability for processing random sparsity.

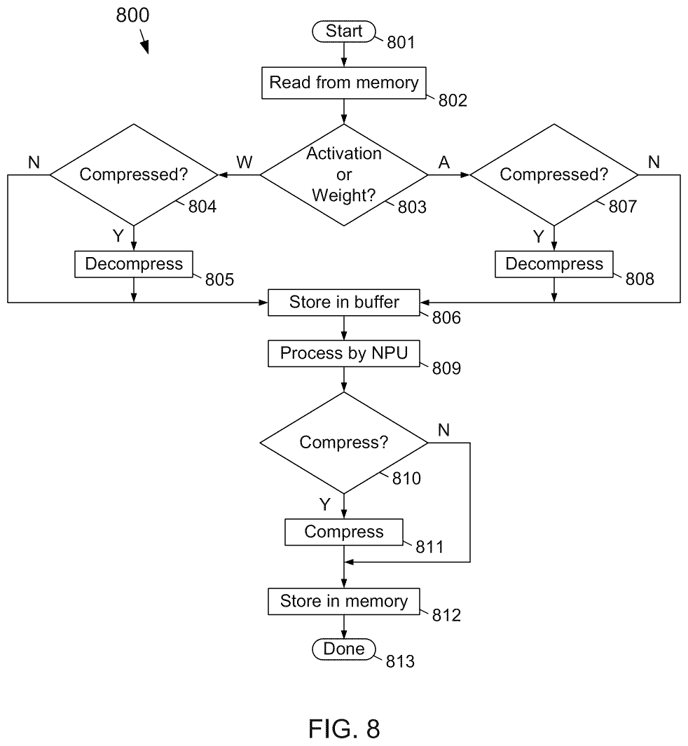

FIG. 8 is a flow diagram of a method 800 for training a neural network model using a memory system, such as memory system 400, according to the subject matter disclosed herein. The method starts at 801 where a layer of the neural network model is being trained. At 802, one or more tensors are read from the memory 401 under control of the controller 404. At 803, the controller determines whether the tensor is a weight tensor or an activation tensor. If the tensor is a weight tensor, flow continues to 804 where the controller determines whether the weight tensor is compressed. If so, flow continues to 805 where the weight tensor is decompressed. Flow continues to 806 where the decompressed weight tensor is stored in an appropriate weight buffer in the NPU 700 (or NPU 710). If, at 804, the weight tensor is not compressed, flow continues to 806.

If at 803, the tensor is an activation tensor, flow continues to 807 where the controller determines whether the activation tensor is compressed. If so, flow continues to 808 where the compressed activation tensor is decompressed. Flow continues to 806, where the decompressed activation tensor is stored in an appropriate activation buffer in the NPU 700. If, at 807, the activation tensor is not compressed, flow continues to 806.

From 806, flow continues to 809 where the NPU 700 processes the tensors stored in the weight and activation buffers to generates output activation tensors (i.e., output feature map values). Flow continues to 810 where the processor determines whether the output activation tensors are to be compressed. If so, flow continues to 811 where the output activation tensors and compressed. Flow continues to 812 where the compressed output activation tensors and metadata are stored in the memory 401. If, at 810, the output activation tensors are not to be compressed, flow continues to 812 where the output activation tensors are stored in the memory 401. Flow continues to 813 where the next layer of the neural network model may be processed, or if all layers have been completed the training epoch is done.

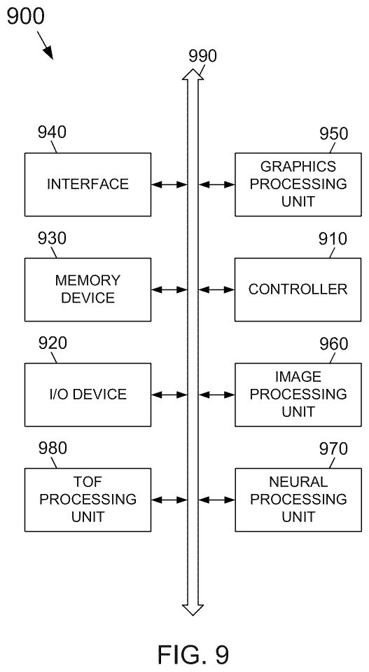

FIG. 9 depicts an electronic device 900 that may include a memory hierarchy that may be used to train a neural network model according to the subject matter disclosed herein. Electronic device 900 and the various system components of electronic device 900 may be formed from one or modules. The electronic device 900 may include a controller (or CPU) 910, an input/output device 920 such as, but not limited to, a keypad, a keyboard, a display, a touch-screen display, a 2D image sensor, a 3D image sensor, a memory 930, an interface 940, a GPU 950, an imaging-processing unit 960, a neural processing unit 970, a TOF processing unit 980 that are coupled to each other through a bus 990. In one embodiment, the 2D image sensor and/or the 3D image sensor may be part of the imaging processing unit 960. In another embodiment, the 3D image sensor may be part of the TOF processing unit 980. The controller 910 may include, for example, at least one microprocessor, at least one digital signal processor, at least one microcontroller, or the like. The memory 930 may be configured to store a command code to be used by the controller 910 and/or to store a user data. In one embodiment, the neural processing unit 970 may be configured as a neural network model that is being trained according to the subject matter disclosed herein.

The interface 940 may be configured to include a wireless interface that is configured to transmit data to or receive data from, for example, a wireless communication network using a RF signal. The wireless interface 940 may include, for example, an antenna. The electronic system 900 also may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service—Time Division Duplex (UMTS-TDD), High Speed Packet Access (HSPA), Evolution Data Optimized (EVDO), Long Term Evolution —Advanced (LTE-Advanced), Multichannel Multipoint Distribution Service (MMDS), Fifth-Generation Wireless (5G), Sixth-Generation Wireless (6G), and so forth.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A memory system for training a neural network model, comprising:
a decompressor unit configured to decompress an activation tensor to a first predetermined sparsity density based on the activation tensor being compressed, and to decompress an weight tensor to a second predetermined sparsity density based on the weight tensor being compressed;
a buffer unit configured to receive the activation tensor at the first predetermined sparsity density and the weight tensor at the second predetermined sparsity density; and
a neural processing unit configured to receive the activation tensor and the weight tensor from the buffer unit and to compute a result for the activation tensor and the weight tensor based on first predetermined sparsity density of the activation tensor and based on the second predetermined sparsity density of the weight tensor.

2. The memory system of claim 1, wherein the first predetermined sparsity density is based on a structured-sparsity arrangement or a random-sparsity arrangement.

3. The memory system of claim 2, wherein the first predetermined sparsity density is based on a 1:4 structured-sparsity arrangement, or a 2:8 structured-sparsity arrangement.

4. The memory system of claim 2, wherein the second predetermined sparsity density is based on a structured-sparsity arrangement or a random-sparsity arrangement.

5. The memory system of claim 4, wherein the second predetermined sparsity density is based on a 1:4 structured-sparsity arrangement or a 2:8 structured-sparsity arrangement.

6. The memory system of claim 1, wherein the second predetermined sparsity density is based on a structured-sparsity arrangement or a random-sparsity arrangement.

7. The memory system of claim 6, wherein the second predetermined sparsity density is based on a 1:4 structured-sparsity arrangement or a 2:8 structured-sparsity arrangement.

8. The memory system of claim 1, wherein the decompressor unit is further configured to decompress the activation tensor to the first predetermined sparsity density using first metadata associated with the activation tensor and is further configured to decompress the weight tensor to the second predetermined sparsity density using second metadata associated with the weight tensor.

9. The memory system of claim 1, further comprising a compressor unit configured to receive and compress the result computed by the neural processing unit, and
a memory further stores the result compressed by the compressor unit.

10. The memory system of claim 9, wherein the compressor unit is further configured to generate metadata associated with the result, and
wherein the memory further stores the metadata.

11. A memory system for training a neural network model, comprising:
a buffer unit configured to receive at least one activation tensor and at least one weight tensor, the activation tensor comprising a first predetermined sparsity density is based on a first structured-sparsity arrangement or a first random-sparsity arrangement, and the weight tensor comprising a second predetermined sparsity density that is based on a second structured-sparsity arrangement or a second random-sparsity arrangement; and
a dual-sparsity neural processing unit configured to receive the activation tensor and the weight tensor from the buffer unit and to compute a result for the activation tensor and the weight tensor based on the first predetermined sparsity density of the activation tensor and based on the second predetermined sparsity density of the weight tensor.

12. The memory system of claim 11, further comprising a decompressor unit configured to decompress the activation tensor to the first predetermined sparsity density and output the activation tensor to the buffer unit.

13. The memory system of claim 12, wherein the decompressor unit is further configured to decompress the weight tensor to the second predetermined sparsity density and output the weight tensor to the buffer unit.

14. The memory system of claim 13, wherein the decompressor unit is further configured to decompress the activation tensor to the first predetermined sparsity density using first metadata associated with the activation tensor and is further configured to decompress the weight tensor to the second predetermined sparsity density using second metadata associated with the weight tensor.

15. The memory system of claim 11, further comprising a decompressor unit configured to decompress the weight tensor to the second predetermined sparsity density and to output the weight tensor to the buffer unit.

16. The memory system of claim 11, wherein the first predetermined sparsity density is based on a 1:4 structured-sparsity arrangement, or a 2:8 structured sparsity-arrangement.

17. The memory system of claim 11, wherein the second predetermined sparsity density is based on a 1:4 structured-sparsity arrangement or a 2:8 structured-sparsity arrangement.

18. The memory system of claim 11, further comprising a compressor unit configured to receive and compress the result computed by the dual-sparsity neural processing unit, and
a memory further stores the result compressed by the compressor unit.

19. The memory system of claim 18, wherein the compressor unit is further configured to generate metadata associated with the result, and
wherein the memory further stores the metadata.
